(19) United States
(12) Patent Application Publication
(10) Pub. No.: US 2024/0281026 A1
(43) Pub. Date: Aug. 22, 2024

(54) MOUNTING ARRANGEMENT FOR A DISPLAY PROTECTOR

(71) Applicant: E.V.I. GMBH, Neuried (DE)

(72) Inventors: Ulrich Kopp, Neuried (DE); Markus Vogtmann, Neuried (DE)

(21) Appl. No.: 18/571,199

(22) PCT Filed: Jun. 15, 2022
(86) PCT No.: PCT/EP2022/066306

§ 371 Date: Dec. 15, 2023

(30) Foreign Application Priority Data
Jun. 16, 2021 (DE) 102021115597

(51) Int. Cl. G06F 1/16; B29C 65/78; B29L 31/34; H04B 1/3888; H05K 5/02

(52) U.S. Cl. CPC G06F 1/1607; B29C 65/7814; H04B 1/3888; H05K 5/0204; B29L 2031/3475; G06F 2200/1612; G06F 2200/1634

(57) ABSTRACT

A mounting device for joining a display protector (1) to a display (2) of an apparatus includes a contact element (3) on which the display protector (1) is positionable and which has a first leg (3a) with a first alignment portion (311a) on which the display protector (1) can be aligned in a first direction, and a second leg (3b) with a second alignment portion (311b) on which the display protector (1) can be aligned in a second direction. In addition, the mounting device includes a leg connecting portion (39) that connects the two legs (3a, 3b) at a fixed angle. Furthermore, the mounting device includes at least a first and at least a second positioning member (4) having a coupling portion (44) which can be coupled to the legs (3a, 3b), and a positioning portion (40) which is aligned with respect to the first alignment portion (311a) and with respect to the second alignment portion (311b) when the first positioning member (4) is coupled to the first leg (3a) and the second positioning member (4) is coupled to the second leg (3b), wherein the apparatus can be brought into contact with at least one positioning portion (40) for alignment in order to align the apparatus and the display protector (1) with respect to each other.

### TECHNICAL FIELD

The present invention relates to a mounting device for a display protector.

### PRIOR ART

In the prior art, a mounting device for a display protector is used to enable a user to attach (join) the display protector to a display of an apparatus.

### SUMMARY OF THE INVENTION

It is the object of the invention to provide a mounting device for a display protector that allows an improved joining of the display protector to a display of an apparatus. The manufacture of the mounting device should also be cost-effective and resource-friendly. The precise positioning of the display protector on the display is particularly important because of the cut-outs in the display protector for sensors, cameras and speakers, for example.

The object is achieved based on the features of claims 1 and 2, respectively. Advantageous further developments are the subject matter of the dependent claims.

A mounting device according to the invention as specified in claim 1 for joining a display protector to a display of an apparatus includes a contact element on which the display protector is positionable and which has a first leg with a first alignment portion on which the display protector can be aligned in a first direction, and a second leg with a second alignment portion on which the display protector can be aligned in a second direction, and a leg connecting portion that connects the two legs at a fixed angle. Furthermore, at least a first and at least a second positioning member is provided with a coupling portion, which can be coupled to the legs, and a positioning portion that is aligned with respect to the first alignment portion and with respect to the second alignment portion when the first positioning member is coupled to the first leg and the second positioning member is coupled to the second leg, wherein the apparatus can be brought into contact with at least one positioning portion for alignment in order to align the apparatus and the display protector with respect to each other.

A mounting device according to the invention as specified in claim 2 for joining a display protector to a display of an apparatus includes a contact element on which the apparatus is positionable and which has a first leg with a first alignment portion on which the apparatus can be aligned in a first direction, and a second leg with a second alignment portion on which the apparatus can be aligned in a second direction. Furthermore, a leg connecting portion that connects the two legs at a fixed angle is provided, and at least a first and at least a second positioning member are provided, which have a coupling portion that can be coupled to the legs and a positioning portion that is aligned with respect to the first alignment portion and with respect to the second alignment portion when the first positioning member is coupled to the first leg and the second positioning member is coupled to the second leg, wherein the display protector can be brought into contact with at least one positioning portion for alignment in order to align the apparatus and the display protector with respect to each other.

An apparatus may be, for example, a phone, smartphone, tablet, or e-book reader. The apparatus has a display. For example, the display is an LCD or OLED screen of a smartphone, including the conventional glass of the display.

A display normal direction is a direction perpendicular to the display when the apparatus is positioned with the frame. A joining surface is a surface where the display and the display protector contact each other during the joining. The joining surface thus lies on the display surface when the apparatus is positioned with the frame. The joining surface can be flat or curved.

Contact elements and positioning members can be designed such that the apparatus can be brought into contact with the mounting device from one side and the display protector can be brought into contact with the mounting device from another side for joining.

Contact elements and positioning members can be designed such that the apparatus and the display protector can be brought into contact with the mounting device from the same side for joining.

In a mounting device, alignment portions and positioning portions are provided as two separate components that can be coupled to one another. The tolerance chain between the alignment portion and the positioning portion is therefore very short and a display protector can be joined to a display with high positioning accuracy.

The device and the display can be displaced in three spatial directions and rotated around the three spatial directions without a contact element. In total, both the apparatus and the display protector have six degrees of freedom in terms of movement. There are three translational degrees of freedom and three rotational degrees of freedom.

A first alignment portion and a second alignment portion serve to limit two translational degrees of freedom and one rotational degree of freedom of the apparatus or the display protector with respect to the mounting device.

Two positioning portions serve to limit two translational and one rotational degree of freedom of the display protector or the apparatus with respect to the mounting device.

Once the apparatus is positioned with the mounting device, the display of the apparatus serves as a further positioning portion for the display protector, which limits the third translational degree of freedom and the remaining rotational degrees of freedom of the display protector with respect to the mounting device and the apparatus.

The apparatus is first positioned on the two legs of the contact element or the positioning members. An edge of the display protector is then brought into contact with the display and at the same time brought into contact with a positioning portion or an alignment portion on the same side of the display protector. At this point, the display protector is positioned translationally with respect to the mounting device and the apparatus. For joining the display protector to the display, the display protector is tilted by one of the two remaining rotational degrees of freedom about at least one of the two spatial directions that are translationally limited by the alignment portions.

A reverse positioning order is also possible, in which the display protector is first positioned with the contact element or the positioning member and then the apparatus is positioned with the display protector with respect to the contact element.

When viewed from the display normal direction, legs can have a simple shape, for example a rectangular one. This has the advantage that the mounting device can be manufactured easily and cost-effectively.

In the case of alignment portions, it is sufficient if an alignment portion has a protrusion, for example in the form of a tip, with which it contacts the apparatus or the display protector. This has the advantage that the user can easily see whether the apparatus or the display protector is correctly positioned on the alignment portion, as the user only has to check one point. The same applies to a positioning portion.

An alignment portion can also have several tips with which it contacts the apparatus or the display protector. This has the advantage that not only a translational degree of freedom can be limited with an alignment portion, but also a rotational degree of freedom can be limited at the same time. The same applies to a positioning portion.

In addition, alignment portions can have curved surfaces, flat surfaces, edges or straight surfaces that abut on the apparatus or the display protector. Areas between the contact points of an alignment portion can thus be recessed so that they are at a distance from the apparatus or the display protector. Thus, the material required to manufacture the mounting device can be reduced. The same applies to a positioning portion.

Furthermore, an alignment portion can have protrusions or recesses that are shaped according to the contour of an apparatus or a display protector. These protrusions and recesses can serve to make it easier for the user to recognize in which orientation the apparatus or the display protector must be positioned with the alignment portion to be brought into precise contact with a designated surface. The same applies to a positioning portion.

Coupling portions can be protrusions, recesses or passages with a certain shape in the positioning members, for example a nipple shape, which can be coupled to corresponding areas in the legs, e.g. nipple receptacles. These corresponding areas are frame coupling portions. For example, coupling portions can be positively coupled to the legs in a press stud-like manner. A spring element that locks the nipple in the leg can be included. However, the connection mechanism between the coupling portions can also be magnetic. The size of the passage or cut-out can be selected in relation to the shape of the coupling portion so that the coupling portion can be coupled to the leg by means of frictional engagement or clamping.

Preferably, frame coupling portions in a leg have as large a distance to each other as possible.

If the positioning member is coupled to a leg, a positioning member substantially projects on one side of the contact element on which also the apparatus or the display protector is positioned on the contact element.

Preferably, all positioning members have the same design and project equally far in the same direction. Thus, all positioning members can be manufactured in the same way and the manufacturing costs can be reduced.

The angle at which the legs are positioned in relation to each other is based on the outer contour of the apparatus. Preferably, the legs are substantially perpendicular to each other.

In a mounting device according to the invention, the positioning members can project beyond the alignment portions of the contact element, when viewed against the display normal direction, when the positioning members are coupled to the legs and the apparatus is positioned with the mounting device.

In a mounting device according to the invention, the contact element or the positioning member can have a support portion where the display and/or the apparatus contacts the mounting device.

The support portion limits the third translational degree of freedom of the apparatus with respect to the mounting device. As a result, the apparatus is clearly positionable in terms of translation and rotation with respect to the mounting device and a joining of the display protector to the display with positional accuracy is supported.

The support portion can be a flat portion against which the display and/or the apparatus lie flat. The support portion can also consist of at least three tips or one edge and one tip. The support portion only needs to be able to define a plane in order to fulfill its purpose.

The support portion can completely cover one side from which the apparatus is brought into contact with the mounting device for joining. With respect to the surfaces surrounding it, the support portion can also be recessed in the mounting device.

The support portion can extend to positioning portions or alignment portions.

Alignment portions of a mounting device according to the invention can be flat surfaces.

The mounting device can be manufactured in whole or in part by means of stamping, laser cutting, water jet cutting or the like.

Flat surfaces are generally easy to manufacture. In this respect, the manufacturing costs can be reduced.

If the flat surface is cut, for example by water jet cutting, the flat surface can be manufactured at a high cutting speed. This can increase machine throughput and reduce manufacturing costs.

In a mounting device according to the invention, alignment portions can be arranged at an angle to the joining surface.

For example, the alignment portions are arranged perpendicular to the joining surface. This has the advantage that the alignment portions can be used as guide surfaces to move the display protector in the display normal direction for joining. When the display protector comes into contact with the display, the display protector is already in the desired position in the joining surface. This prevents the display protector from having to be moved in the joining surface when it is already in contact with the display. This effectively prevents scratches on the display and the display protector sticking in a wrong position.

An alignment portion can also be inclined to the joining surface. Preferably, the alignment portion is then inclined such that it forms an acute angle with the display or the apparatus with respect to the side from which the display protector is positioned with the alignment portion. If the display protector is pressed in the direction of the alignment portions during joining to ensure that it is correctly positioned against the alignment portions, the display protector simultaneously experiences a force component in the direction of the display to which it is to be joined. Thus, the display protector is already pressed onto the display by aligning it in the joining surface. This prevents the formation of bubbles in the joining surface from the very first contact between the display protector and the display and simplifies the joining for the user.

The same applies to a positioning portion.

Alignment portions of a mounting device according to the invention are aligned with each other at an angle in the joining surface.

The angle at which the alignment portions are aligned with each other is based on the outer contour of the display protector or the apparatus. Preferably, the alignment portions are substantially perpendicular to each other, or at least edges of alignment portions located in the joining surface are substantially perpendicular to each other if the alignment portions are not arranged perpendicular to the joining surface.

The same applies to a positioning portion.

Alignment portions of a mounting device according to the invention can be connected by means of an alignment connecting portion.

The alignment connecting portions serve to position alignment portions in relation to each other. The alignment connecting portions are formed such that the display protector or the apparatus has enough play at corresponding points so that the apparatus or the display protector can be brought into contact with the alignment portions at the designated points.

For example, the alignment connecting portions can have an arc shape when viewed from the display normal direction.

Viewed from the display normal direction, alignment portions can also have a corner or an edge or be polygon-shaped. This can increase play or distance with regard to the apparatus or the display protector and ensure correct joining.

The first and second legs of a mounting device according to the invention can be arranged in such a way that an L-shape is obtained for the contact element.

The legs can have different lengths. The different lengths can be based on the dimensions of the display protector or the apparatus. Thereby, it is possible to show the user in which orientation the display protector or the apparatus should be positioned with the contact element, making it easier to handle the mounting device.

The legs can also have the same length. The advantage of this is that the legs can be processed with the same tool. As a result, the manufacturing costs for the mounting device can be reduced.

In addition, two L-shaped contact elements abutting on adjacent corners of the apparatus can be used for an apparatus. The two L-shaped contact elements can have the same design. This means that a large number of identical contact elements can be manufactured, reducing the manufacturing costs for a single contact element.

In this case, the display protector can be positioned in relation to the apparatus by abutting it on two adjacent alignment portions of a leg of a first contact element and a second contact element. The alignment portions can be designed in such a way that they are positioned as far apart as possible in a longitudinal or transverse direction and abut on the apparatus or the display protector. This supports joining with positional accuracy.

A contact element of a mounting device according to the invention can have a third leg with a third alignment portion, which a leg connecting portion connects with the first and/or second leg at a fixed angle.

The third alignment portion can further limit a degree of freedom of the apparatus or the display protector in a translational direction.

If, with respect to the apparatus or the display protector, two alignment portions are arranged to face each other on different sides of the apparatus or the display protector, a range of movement can be defined in which the apparatus or the display protector can move in a translational direction during joining. Thus, three alignment portions can be used to fix the position of the apparatus or the display protector in one translational direction and limit its movement in another translational direction. This supports joining with high positioning accuracy.

The legs of a mounting device according to the invention can be arranged such that a U-shape is obtained for the contact element.

If two alignment portions are arranged to face each other regarding the apparatus or the display protector and the two alignment portions are provided in different legs, a U-shape is obtained for the contact element.

However, it is also possible to position two legs on a central leg in such a way that a T-shape is obtained for the contact element. The central leg can have alignment portions on two sides that are opposite with respect to the central leg. With this design, the one side of the T-shaped contact element can be provided as the other side of the contact element for joining a different display protector to a different apparatus. This increases the functionality of the mounting device and reduces the manufacturing costs compared to two separate mounting devices for two different apparatuses or display protectors.

In this respect, the legs can have different lengths. The different lengths can be based on the dimensions of the display protector or the apparatus. Thereby, it is possible to show the user in which orientation the display protector or the apparatus should be positioned with the contact element, making it easier to handle the mounting device.

For example, the legs can have lengths that correspond to the width and length of an apparatus or a display protector. However, the legs can also have lengths that are smaller, for example half the width and length of an apparatus or a display protector. This can save material to manufacture the mounting device and reduce manufacturing costs.

The legs can also have the same length. The advantage of this is that the legs can be processed with the same tool. As a result, the manufacturing costs for the mounting device can be reduced.

The legs of a mounting device according to the invention can have a different length and be arranged such that a J-shape is obtained for the contact element.

If at least two legs that face each other have different lengths, a J-shape is obtained for the contact element. The short leg can be positioned in such a way that it exposes operating elements or protrusions on the apparatus. This supports joining with positional accuracy.

A mounting device according to the invention can have at least one further positioning member with a positioning portion, which is arranged on the first leg, the second leg or the third leg.

The third positioning portion can further limit a degree of freedom of the apparatus or the display protector in a translational direction.

If, with respect to the apparatus or the display protector, two positioning portions are arranged to face each other on different sides of the apparatus or the display protector, a range of movement can be defined in which the apparatus or the display protector can move in a translational direction during joining. Thus, three positioning portions can be used to fix the position of the apparatus or the display protector in one translational direction and limit its movement in another translational direction. This supports joining with high positioning accuracy.

Positioning members of a mounting device according to the invention can be coupled to one another by means of positioning member coupling portions.

This has the advantage that the coupled positioning members support each other and the mounting device therefore has increased stability. This allows joining with high precision.

For example, positioning members that abut on different sides of the apparatus or the display protector during joining can be coupled to each other. The positioning members then include an angle that can be based on the angles of alignment portions and positioning portions.

For example, positioning members that are perpendicular to each other can be coupled. The positioning members then prevent tilting of the respective other positioning member.

The positioning members can be connected to each other via several legs. Either couplings between a positioning member and a leg may be omitted or couplings between two legs whose positioning members are coupled may be omitted.

The positioning member coupling portions, for example, can be designed such that there is a slot in one positioning member, wherein there is a web in the other positioning member. The slot has the width of the web and can therefore be connected to the web.

If the web is slightly wider than the slot, the web can be secured in the slot by frictional engagement. The oversize by which the web must be wider than the slot depends on the material properties of the positioning members. If a metal material is used that has a large modulus of elasticity, a few 1/1000 mm are sufficient for the oversize. If a material with a low modulus of elasticity is used, such as cardboard, MDF, HDF, plywood, etc. or a mix of materials, a few 1/100 mm are sufficient for the oversize.

However, the design of the positioning coupling portion can also be any combination of projection and recess in the corresponding supporting members. The design must only serve to ensure that the projection can be supported on the recess with respect to its projection axis in such a way that the projection can maintain its orientation even under the influence of external force.

A positioning portion of a mounting device according to the invention can be provided with an adhesive element that comes into contact with the apparatus or the display protector such that the positioning member adheres to the apparatus or the display protector.

An alignment portion of a mounting device according to the invention can be provided with an adhesive element that comes into contact with the apparatus or the display protector such that the contact element adheres to the apparatus or the display protector.

As a result, the position of the apparatus or the display protector in which it is placed in the mounting device for joining can be fixed. This has the advantage that the user no longer has to pay attention to the relative positions of the apparatus or the display protector and the mounting device when he has positioned the apparatus or the display protector with the mounting device. The user can therefore concentrate fully on joining the display protector to the display. This improves the handling of the mounting device and supports a precise joining process.

For example, adhesive areas can be used as adhesive elements. Adhesive areas are very affordable to manufacture. Thus, the mounting device can be manufactured in a cost-effective manner.

Magnets can also be used as adhesive elements. This has the advantage that the adhesive elements can be used several times for a joining process. This conserves natural resources.

Adhesive strips with peel-off elements can also be used as adhesive elements. Several adhesive strips are provided on top of each other. In this case, an unused adhesive strip is revealed when a top adhesive strip is peeled off. This design combines the advantages of magnets and adhesive areas.

Adhesive elements can also be designed to form a positive fit with the apparatus or the display protector, such as hooks or protrusions that engage in certain recesses, such as a microphone input, a headphone jack and the like, of the apparatus or the display protector.

Furthermore, the adhesive elements can be designed so that they adhere to or abut on the display of the apparatus or the display protector in the display normal direction.

An adhesive element of a mounting device according to the invention can be covered with an adhesive element cover.

This ensures that the adhesive element does not get dirty. This is to ensure that the adhesive element can provide the desired function at least until the cover has been removed.

The adhesive element cover can be a plastic film, for example, which is applied to an adhesive strip as adhesive element. The adhesive element cover can also be a paper layer with an additional coating on one side that makes it easier to detach the paper layer from the adhesive element. In the case of the paper film, the mounting device may be recyclable and therefore manufactured in an environment-friendly way.

If the adhesive element is magnetic, a rigid cover, for example made of plastic or cardboard, which is attached to the mounting device by positive or frictional engagement, can also serve as an adhesive element cover.

A contact element of a mounting device according to the invention can have a grip portion.

A grip portion can also be integrated into a positioning member.

The grip portion allows easy positioning of the contact element with the apparatus or the display protector without the user having to touch other areas of the mounting device.

For example, if positioning portions or alignment portions, which are provided with an adhesive element, are exposed in order to position an apparatus or a display protector thereon, the user can guide the apparatus or the display protector and the mounting device towards each other without the adhesive elements coming into contact with elements other than the designated areas of the apparatus or the display protector. This prevents soiling of the adhesive elements and undesirable slipping of the mounting device and the apparatus or the display protector in relation to each other.

A grip portion can be arranged in a leg, a leg connecting portion or an alignment connecting portion. Preferably, the grip portion is arranged at a point of the contact element around which the occurring moment effects are largely balanced by the forces that occur when the apparatus or the display protector is positioned on the contact element.

In the event that occurring moments are not completely balanced, the user can counteract the remaining moments via the grip portion and prevent the mounting device from slipping.

If, for example, the contact element is L-shaped, it is advisable to arrange the grip portion in an area where the two legs converge. In this case, the moment effects of the forces applied to the first and second alignment portions balance each other to a certain extent, as the grip portion is located in a central area between the alignment portions, viewed from the direction from which the forces are applied.

Viewed in the display normal direction, a grip portion can be part-circular. The diameter of the pitch circle determines the grip of the grip portion. A large diameter increases the grip of the grip portion.

A diameter of 1 to 2 cm is advisable. In this case, the grip of the grip portion is very good. In addition, the grip portion in this size can be arranged well in the central area of the legs without requiring much additional material. Thus, a resource-saving manufacturing is possible.

The grip portion can have a rough, knurled, corrugated or serrated surface to increase the grip.

The grip portion can also have a rectangular plate form that projects from the contact element in the display normal direction. The rectangular plate form is easy to manufacture, which keeps manufacturing costs low. In addition, a plate form can be gripped very well, which supports joining with high accuracy.

The grip portion can be integral with the contact element. The grip portion may also be designed so that it can be coupled to the contact element.

For example, the grip portion can have a rectangular plate form and be coupled to a slot-shaped opening in the contact element. The width of the slot can correspond to the thickness of the plate to enable easy coupling.

The grip portion can also have a certain oversize, which prevents the grip portion from slipping out of the designated opening in the contact element by means of frictional engagement.

A leg connecting portion of a mounting device according to the invention can be integral with legs.

In this case, the number of parts of the mounting device is reduced and the mounting device can therefore be manufactured cost-effectively.

A leg connecting portion of a mounting device according to the invention can be a separate connectable part.

The leg connecting portion can be formed from a correspondingly shaped portion of a first leg and a matching correspondingly shaped portion of another leg.

A leg connecting portion can have a positive fit, for example if two components, such as two legs, can be coupled together as in a puzzle. A coupling surface that forms a meander-shaped T-shape when viewed from the display normal direction is also possible.

A leg connecting portion can have a force fit, such as by means of a press stud fastener or a hook and loop fastener, can be magnetic or can be realized by means of adhesive surfaces.

For example, the leg connecting portion can be designed so that, in the display normal direction, one leg has only half of its thickness in one area and another leg has half of its thickness in one area in the opposite direction to the display normal direction. The two legs have adhesive surfaces on the areas that are reduced in thickness, so that the two legs are joined together by means of the adhesive surfaces, resulting in a uniform thickness of the contact element in the entire leg connecting area.

In addition, the leg connecting portion can be designed to provide detent elements and axis alignment elements. The axis alignment elements are used to couple two legs with respect to a common axis. The two legs can rotate relative to each other around the common axis. The detent elements can be coupled separately from the axis contact elements so that they can lock the rotation of the two legs around the common axis. This means that an angle of legs to each other and of alignment portions or positioning portions to each other can be variably adjusted and the mounting device can be used in a variety of ways for different apparatus or display shapes.

A height of a positioning member of a mounting device according to the invention can be adjusted in the plate thickness direction such that the positioning member does not touch the ground when the apparatus is positioned with the positioning member.

The mounting device according to the invention may be used in the following order: First, an apparatus is positioned on a ground. The mounting device is then positioned on the apparatus so that the positioning portions of the positioning members contact the designated points of the apparatus. In this respect, the positioning members from the contact element point downwards in a direction of gravity. The support portion rests on the display and/or the apparatus.

For a perfect joining of the display protector to the display, it may be necessary that the support portion does not detach from the display and/or the apparatus.

For this purpose, the height of the positioning member is adjusted so that it does not touch the ground when the apparatus is positioned with the mounting device, as the support portion could otherwise detach from the display and/or the apparatus. This supports a high precision joining.

The thickness of a contact element of a mounting device according to the invention can be provided such that the contact element does not touch the ground when the apparatus is positioned with the contact element.

The mounting device according to the invention may be used in the following order: First, an apparatus is positioned on a ground. The mounting device is then positioned on the apparatus so that the alignment portions of the contact element contact the designated points of the apparatus and/or the display. In this respect, the positioning members from the contact element point upwards in a direction of gravity. The support portion rests on the display and/or the apparatus.

For a perfect joining of the display protector to the display, it may be necessary that the support portion does not detach from the display and/or the apparatus.

For this purpose, the thickness of the contact element is provided so that it does not touch the ground when the apparatus is positioned with the mounting device, as the support portion could otherwise detach from the display and/or the apparatus. This supports a high precision joining. In other words, the thickness of the contact element is thinner than the apparatus.

A positioning member of a mounting device according to the invention can be configured such that it is displaceable in a coupling portion perpendicularly to the joining surface. In addition, the positioning member can be provided with an adhesive element on a side facing a ground, with which the positioning member is positionable on the ground such that the positioning member adheres to the ground and the display and/or the apparatus contact the support portion.

Due to the displaceability of the positioning members perpendicular to the joining surface, it is possible to variably adjust how far the positioning members project downwards in a direction of gravity when the apparatus is positioned with the mounting device. This ensures that the positioning members do not touch the ground and the support portion does not detach from the apparatus and/or the display, even if the positioning members touch the ground. An excess length of the positioning members then projects upwards from the contact element in a direction of gravity.

For example, slots can be provided in the contact element and positioning members can have webs.

If the web is slightly wider than the slot, the web can be secured in the slot by frictional engagement. The oversize by which the web must be wider than the slot depends on the material properties of the positioning members. If a metal material is used that has a large modulus of elasticity, a few 1/1000 mm are sufficient for the oversize. If a material with a low modulus of elasticity is used, such as cardboard, MDF, HDF, plywood, etc. or a mix of materials, a few 1/100 mm are sufficient for the oversize.

If one side of a positioning member touches the ground and an adhesive element is provided on this side, the mounting device adheres to the ground by means of the adhesive elements on the bottom side of the positioning members. This has the advantage that the mounting device does not slip relative to the ground even under the effect of external force or a force that arises during the joining. This supports a high precision joining.

An adhesive element can be arranged on a side of the contact element facing the ground of a mounting device according to the invention, with which the contact element is positionable on the ground such that the contact element adheres to the ground with the adhesive element and the display and/or the apparatus contact the support portion.

This has the advantage that the mounting device does not slip relative to the ground even under the effect of external force or a force that arises during the joining. This supports a high precision joining.

The adhesive support can be made of rubber, for example. Alternatively, the adhesive support can consist of a double-sided adhesive tape that has covers on both adhesive sides.

The contact element of a mounting device according to the invention can have a plate form, and the one side can be a plate upper side and the other side can be a plate bottom side.

The plate form allows manufacturing the contact element of the mounting device without an elaborate mold, such as that required for plastic die casting. This reduces the manufacturing costs.

For example, cardboard, MDF, HDF, plywood, etc., or a mix of materials can be considered as material for a plate-form blank. Biodegradable, renewable or recyclable raw materials can be used. All stable flat materials are suitable.

The surface of the contact element and of the blank can have steps or corrugations or another surface structure; it can have a uniform thickness or it can have regionally different thicknesses. Such elements of the surface structure can be used as a cut-out, for example. Moreover, such a surface structure can make it easier for the user to grip the contact element, thus improving the handling of the mounting device. The strength can also be increased by a suitable surface structure.

The thickness for the plate form can be in the range of from 0.8 mm to 5 mm, for example, preferably between 1.5 and 2.5 mm. The thickness of the material can be based on the material properties. High-strength materials can be made thinner and low-strength materials may tend to be thicker. This allows for ease of manufacture. For example, less energy is required to manufacture the contact element by means of laser cutting if the thickness of the blank is small. Thus, the contact element can be manufactured in a cost-effective, energy-efficient, economical and ecological manner.

Besides, it can thus be ensured that the mounting device has sufficient rigidity so that relevant alignment portions and positioning portions remain positioned relative to each other during the joining. This enables high precision joining.

In addition, a plate-form design has the advantage that the contact elements have a small space requirement, which can reduce transportation and storage costs.

Furthermore, the plate form allows the mounting devices to be manufactured so that they are lightweight. This can reduce transportation costs and the resulting environmental impact.

The mounting device can be provided to the user as a kit or as a fully assembled mounting device.

A frame coupling portion of a mounting device according to the invention can consist of an elongated cut-out that is continuous in the plate thickness direction and can be coupled to the coupling portion of the positioning member.

This enables a manufacturing method such as stamping, laser cutting, water jet cutting or the like. Thus, a mounting device can be manufactured in a cost-effective manner.

An area on the plate bottom side of the contact element of a mounting device according to the invention can serve as a stop that limits the movement of a positioning member in the plate thickness direction.

This area can be the plate bottom side. However, this area can also project from or be recessed on the plate bottom side in the plate thickness direction.

The design with a stop for the positioning member makes it easier for the user to assemble the mounting device.

A contact element of a mounting device according to the invention can additionally have a plate-shaped coupling lock that is connected to the contact element in the frame coupling portion by means of at least one web.

This has the advantage that the frame coupling portion is protected from soiling until the coupling lock is released from the contact element. This ensures the functioning of the mounting device.

A plate-shaped positioning member of a mounting device according to the invention can be connected to the contact element by means of at least one web.

The positioning member can be arranged in an area surrounded by the legs, for example. In the case of an L-shaped contact element, a positioning member can be arranged in the area spanned by the legs. In the case of a U-shaped contact element, a positioning member can be arranged within the U-shape.

This reduces the amount of material required to manufacture the mounting device and it can be manufactured in a cost-effective and resource-efficient manner. Furthermore, the mounting device can be stored to save space and in stacks.

If the legs are separate components that are connected with leg connecting portions, positioning members can be arranged in the extension of the legs and the legs are arranged parallel to each other and connected to each other with at least one web. Alternatively, in this case, the legs can also be arranged parallel to each other and positioning members can be arranged between them, wherein legs with positioning members can be connected by means of at least one web.

Positioning members can also be connected to each other by means of at least one web.

A positioning member can be arranged in an area recessed between contact points of an alignment portion that is at a distance from the apparatus or the display protector. Thus, the material required to manufacture the mounting device can be reduced.

In a mounting device according to the invention, a central plate can be connected to the contact element by means of a web.

The central plate is preferably arranged in an area that is surrounded by the legs of the contact element. In the case of an L-shaped contact element, a central plate can be arranged in the area spanned by the legs. In the case of a U-shaped contact element, a central plate can be arranged within the U-shape.

The central plate can also be provided with adhesive elements on both sides. In this case, the central plate serves as an adhesive support.

A positioning member of a mounting device according to the invention can be connected to the central plate by means of at least one web.

In this case, a positioning member is preferably arranged within the central plate.

If many supporting members or other components are required for the mounting device, supporting members can also be arranged outside the central plate and outside the contact element.

This reduces the amount of material required to manufacture the mounting device and it can be manufactured in a cost-effective and resource-efficient manner. Furthermore, the mounting device can be stored to save space and in stacks. In addition, the individual parts of the mounting device can be designed to be stable for transportation and damage to the individual parts of the mounting device during transportation can be prevented.

In a mounting device according to the invention, a smoothing-out member arranged within the central plate can be connected to the central plate by means of at least one web.

The smoothing-out member is used to sweep over the display protector with pressure in the direction of the display protector during or after joining a display protector to a display. Air bubbles that have formed between the display protector and the display during the joining are thus moved to the outside and removed from between the display protector and the display.

At least one positioning member of a mounting device according to the invention can be connected to the smoothing-out member by means of a web within the smoothing-out member.

The smoothing-out member of a mounting device according to the invention can be positioned in the central plate so as to cover an area of the apparatus projecting against the display normal direction on a bottom side of the apparatus when the apparatus is positioned with the contact element.

The projecting area of the apparatus can be a camera, a fingerprint sensor, a button or the like.

If the smoothing-out member is disposed in the central plate in this area, the central plate can serve as a positioning aid once the smoothing-out member has been removed. If the apparatus is placed on the central plate accordingly, the upper side of the apparatus and the display of the apparatus are stable and parallel to the ground despite projecting areas of the apparatus. This simplifies precise joining.

In a mounting device according to the invention, an apparatus holding element arranged within the central plate can be connected to the central plate by means of at least one web.

Thus, residual material is used to provide an apparatus holding element. By eliminating the need to manufacture a separate apparatus holding element, the mounting device helps to conserve resources.

By means of the apparatus holding element, the apparatus can be placed on a ground in such a way that a user in front of whom the apparatus is placed can clearly see the display without having to hold the apparatus.

For example, the apparatus holding element can serve to hold the apparatus on a flat ground at a certain angle relative to the ground. This angle is in the range of 50° to 80°, for example. In this angle range, the apparatus inserted in the apparatus holding element takes an orientation that is ergonomic with respect to the user's viewing direction.

The width of a web is preferably 0.1 mm to 1 mm. The width of the webs is preferably designed so that the coupling locks can be manually released from the contact element. Thus, the width of the webs strongly depends on the material of the blank of the contact element, on the thickness of the blank and on the number of webs by which the coupling lock is connected to the contact element. However, the width of a web or the number of webs also depends on the size of the component that is fastened with the webs.

For example, a coupling lock element has a small number of webs, whereas a central plate or a smoothing-out member has more webs or thicker webs, as they are larger than the coupling lock elements and a greater press-out force can be exerted on them at the same surface pressure.

This reduces the amount of material required to manufacture the mounting device and it can be manufactured in a cost-effective and resource-efficient manner. Furthermore, the mounting device can be stored to save space and in stacks. In addition, the individual parts of the mounting device can be designed to be stable for transportation and damage to the individual parts of the mounting device during transportation can be prevented.

A positioning portion of a mounting device according to the invention can have operating element cut-outs, which expose projecting areas of the apparatus or the display in a direction parallel to the joining surface.

This serves to ensure that the display alignment portions do not get caught on projecting areas of the apparatus, such as buttons or other operating elements, or of the display when the mounting device is placed onto the apparatus or the display. Thus, high precision joining is made possible.

The contact element of a mounting device according to the invention can have a labeling area.

The labeling area can be used to imprint an identification number. If a defect, such as a point or sharp edge that could be dangerous for the user, occurs in the mounting devices during production, the affected mounting devices can be easily identified and removed from circulation. This helps to ensure safe handling of the mounting device.

The labeling area can also be provided, for example, in a positioning member, a grip portion, a central plate, a smoothing-out member or an apparatus holding element.

The labeling area can be recessed or projecting in relation to the surrounding surface.

### BRIEF DESCRIPTION OF THE FIGURES

FIG. 1 shows a perspective view of a first embodiment of a mounting device according to the invention.

FIGS. 2a to 2c show different variants of positioning members of the first embodiment of the mounting device according to the invention.

FIG. 3 shows an initial mounting step when using the first embodiment of the mounting device according to the invention.

FIG. 4 shows a further mounting step when using the first embodiment of the mounting device according to the invention.

FIG. 5 shows a further mounting step when using the first embodiment of the mounting device according to the invention.

FIG. 6 shows an alternative application of the first embodiment of the mounting device according to the invention.

FIG. 7 shows an initial mounting step when using a second embodiment of the mounting device according to the invention.

FIG. 8 shows a further mounting step when using the second embodiment of the mounting device according to the invention.

FIG. 9 shows a further mounting step when using the second embodiment of the mounting device according to the invention.

FIG. 10 shows a perspective view of a third embodiment of the mounting device according to the invention.

FIG. 11 shows an initial mounting step when using the third embodiment of the mounting device according to the invention.

FIG. 12 shows a further mounting step when using the third embodiment of the mounting device according to the invention.

FIG. 13 shows a further mounting step when using the third embodiment of the mounting device according to the invention.

FIG. 14 shows a perspective view of a fourth embodiment of the mounting device according to the invention.

FIG. 15 shows an initial mounting step when using the fourth embodiment of the mounting device according to the invention.

FIG. 16 shows a further mounting step when using the fourth embodiment of the mounting device according to the invention.

FIG. 17 shows a further mounting step when using the fourth embodiment of the mounting device according to the invention.

FIG. 18 shows a perspective view of a fifth embodiment of the mounting device according to the invention.

FIG. 19 shows an initial mounting step when using the fifth embodiment of the mounting device according to the invention.

FIG. 20 shows a further mounting step when using the fifth embodiment of the mounting device according to the invention.

### DETAILED DESCRIPTION OF THE EMBODIMENTS

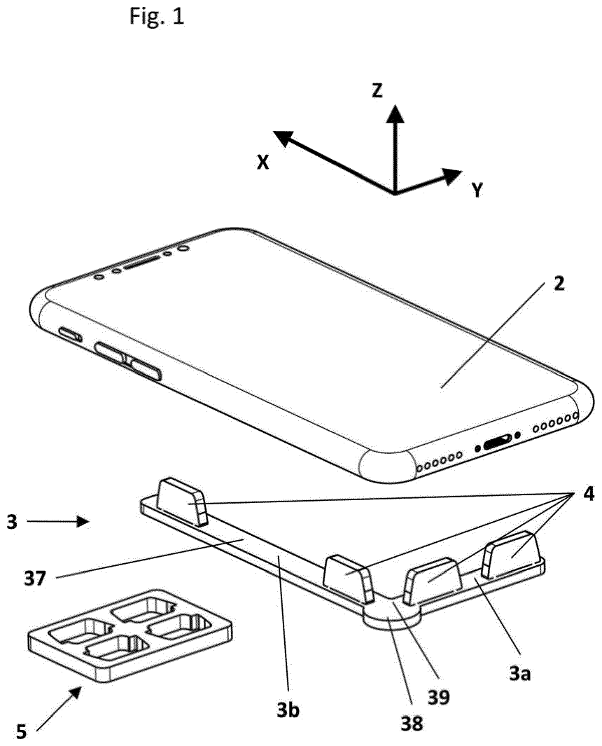

FIG. 1 shows a first embodiment of the mounting device according to the invention, which is used for a smartphone. The mounting device consists of an L-shaped contact element 3. The contact element 3 has two legs 3a, 3b, which are perpendicular to each other. The first leg 3a points in the transverse direction Y, the second leg 2b points in the longitudinal direction X. Two positioning members 4 are coupled to each of the first and second legs 3a and 3b. The positioning members 4 project from the contact element in the display normal direction Z. The legs 3a, 3b are connected by means of the leg connecting portion 39.

The leg connecting portion 39 has a cylindrical grip portion 38. The grip portion 38 provides the user with an area that is easy to grip. This allows the user to easily position the mounting device using the grip portion 38.

In the present embodiment, the surface of the contact element 3, which faces in the display normal direction Z, forms a support portion 37. The apparatus with display 2 can be placed on the support portion.

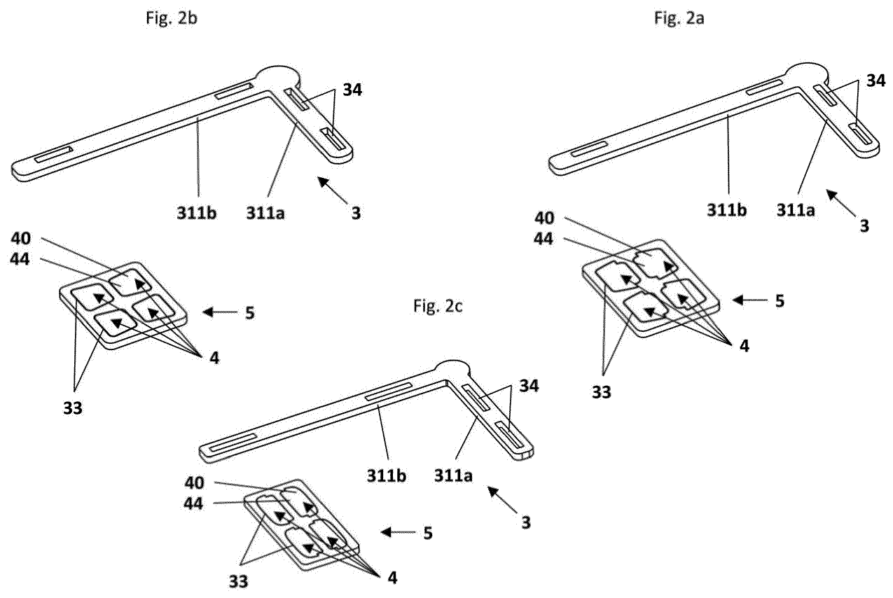

The positioning members 4 each have a positioning portion 40 on the sides facing the apparatus (see FIGS. 2a to 2c). With its side surfaces against the longitudinal direction X and against the transverse direction Y, the apparatus can be brought into contact with the positioning portions 40. In addition, a display protector 1 can be brought into contact with the positioning portions 40. Alternatively, the display protector 1 can be brought into contact with the alignment portions 311a, 311b on the sides of the legs facing the apparatus.

Furthermore, the display protector 1 can be positioned on the display 2 of the apparatus. Thus, using the mounting device, the display protector 1 and the display 2 of the apparatus can be positioned clearly relative to each other in all three spatial directions.

In an initial state, the positioning members 4 are provided in corresponding cut-outs of a smoothing-out member 5. The positioning members 4 are attached to the smoothing-out member 5 with webs 33. The smoothing-out member 5 is connected to the alignment portions 311a, 311b of the contact element 3 by means of webs 33.

Viewed from the display normal direction Z, the radius of the corners of the smoothing-out member 5 is smaller than the radius of the leg connecting portion 39 in the XY direction. This allows the smoothing-out member 5 to be positioned close to the leg connecting portion 39 in the initial state. The positioning member 4, the smoothing-out member 5 and the contact element 3 have a plate form with the same thickness each. The webs 33 are designed so that they can be severed manually. This means that the positioning member 4, the smoothing-out member 5 and the contact element 3 can be easily separated from each other.

FIGS. 2a to 2c show different variants of positioning members 4, each of which is provided in a smoothing-out member 5 by means of webs 33. Each positioning member 4 has a coupling portion 44 and a positioning portion 40.

Each leg 3a, 3b of the contact element 3 has two frame coupling portions 34. The frame coupling portions 34 are rectangular through-holes whose width corresponds to the thickness of the plate from which the contact element 3, the positioning members 4 and the smoothing-out member 5 are made. The frame coupling portions 34 are arranged on each leg 34 such that they have as large a distance to each other as possible.

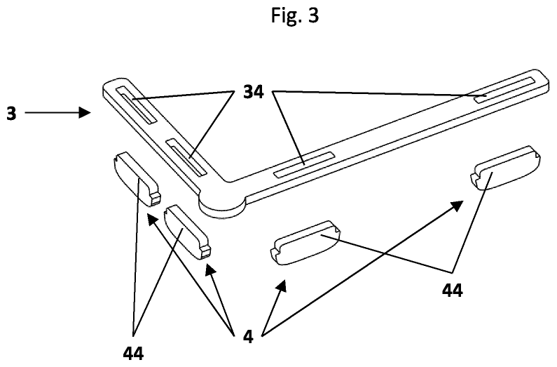

As shown in FIG. 3, a coupling portion 44 of a positioning member 4 can be inserted into a frame coupling portion 34 of a contact element 3 until the positioning portion 40 abuts against the contact element 3. Thus, a positioning member 4 can be coupled to the contact element 3.

Each leg 3a, 3b has an alignment portion 311a, 311b. The alignment portions 311a, 311b are perpendicular to each other. The alignment portions 311a, 311b are connected to each other with a radius which, when viewed from the display normal direction Z, is smaller than a corresponding radius of a corner of an apparatus, a display 2 or a display protector 1.

The positioning portion 40 can be brought into contact with the apparatus or the display 2 or the display protector 1 when the positioning member 4 and the contact element 3 are coupled to each other. Accordingly, an alignment portion 311a, 311b can be brought into contact with the display protector 1 or the apparatus and the display 2, respectively.

The positioning member 4 of FIG. 2a is provided with a shoulder between the coupling portion 44 and the positioning portion 40. The shoulder is in contact with the alignment element 3 when the positioning member 4 is coupled to the alignment element 3. A height of the positioning portion 40 is greater than a thickness of the apparatus in the display normal direction Z.

Thus, as shown in FIG. 6, the mounting device from FIG. 2a can be positioned under the apparatus in the display normal direction Z. In this case, the positioning portions 40 project beyond the apparatus in the display normal direction Z and the positioning portions 40 contact the apparatus on a side that points in a direction perpendicular to the display normal direction Z. Furthermore, a display protector 1 can also be brought into contact with the positioning portions 40 while it is brought into contact with the display 2 of the apparatus.

The positioning member 4 in FIG. 2b has no shoulder. However, the positioning member 4 narrows in the direction of the coupling portion 44, so that the positioning portion 40 is significantly wider than the coupling portion 44. The length of a frame coupling portion 34 of the contact element 3 is exactly adapted to a width of the positioning member 4, so that the tapered sides of the positioning member 4 abut against the contact element 3 at a certain point when the coupling portion 44 is inserted into the frame coupling portion 34. This makes it possible to determine the amount by which the positioning portion 40 projects from the contact element 3 in the display normal direction Z when a positioning member 4 is coupled to the contact element 3.

The positioning member 4 in FIG. 2c has a shoulder. A height of the positioning portion 40 is less than a thickness of the apparatus in the display normal direction Z. Thus, the mounting device can be positioned on top of the apparatus in the display normal direction Z without the positioning members 4 touching a plane ground on which the apparatus rests when the positioning member 4 and the contact element 3 are coupled.

FIG. 3 shows an initial mounting step when using the first embodiment. Accordingly, the positioning members 4 are first coupled to the contact element 3.

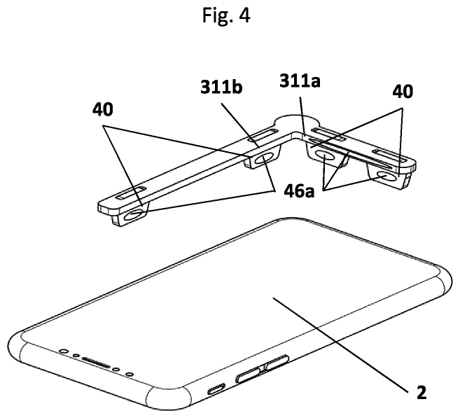

In FIG. 4, the apparatus is positioned on a plane ground with the display facing upwards in the display normal direction Z. The mounting device is then brought into contact with the apparatus from above.

In order to simplify a mounting process, adhesive elements 46a are provided on the positioning portions 40, which are brought into contact with side surfaces of the apparatus.

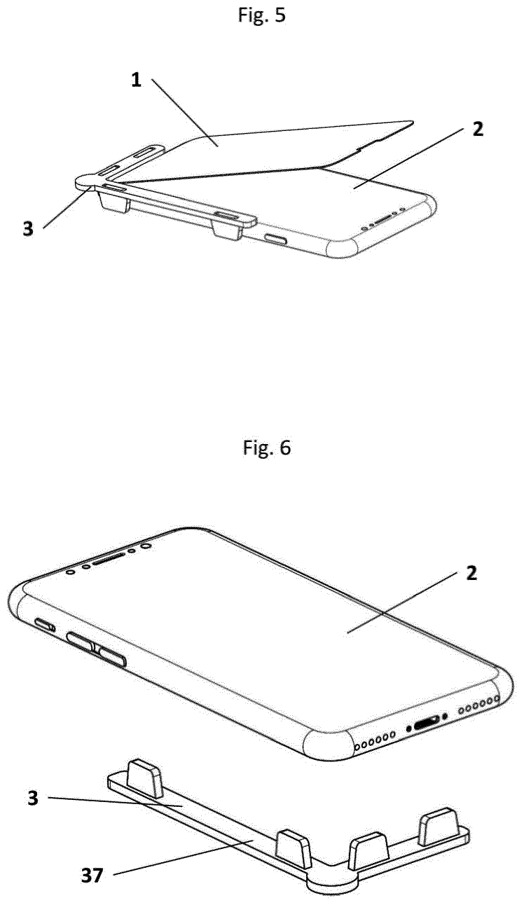

As shown in FIG. 5, this ensures that the mounting device stably adheres to the apparatus and reliably maintains its position. The user can concentrate fully on positioning the display protector on the alignment portions 311a, 311b.

An adhesive element 46a is also provided on the alignment portion 311a. If the display protector 1 abuts the alignment portion 311a, as shown in FIG. 4, the adhesive element 46a prevents the display protector 1 from being displaced in the transverse direction Y and the longitudinal direction X. The user can concentrate fully on tilting the display protector around the transverse direction Y in order to join the display protector 1 to the display 2.

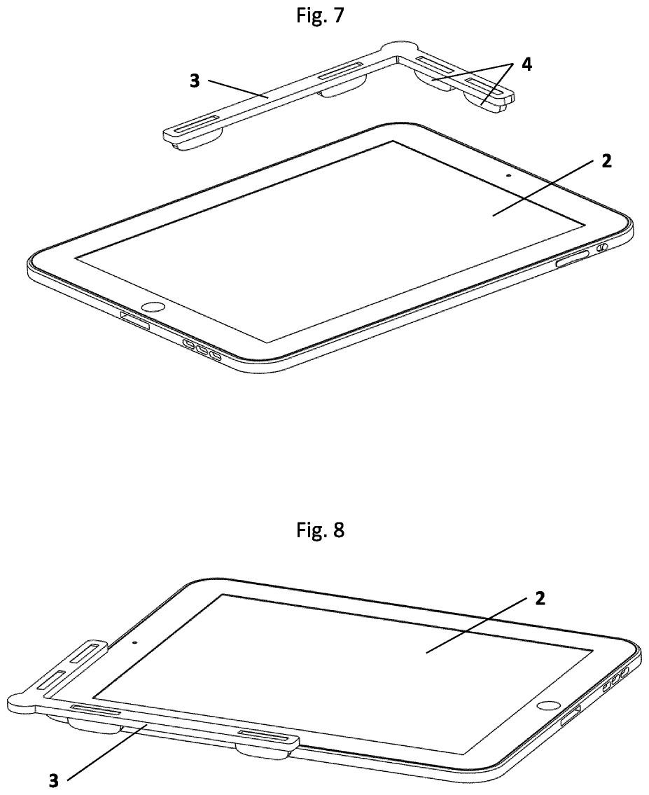

FIG. 7 shows a second embodiment of a mounting device according to the invention. In the present embodiment, the mounting device is used for a tablet with a large display. First, four positioning members 4 are coupled to the contact element 3.

FIG. 8 shows how the contact element 3 is positioned on the apparatus in the display normal direction Z, wherein the positioning portions 40 of the positioning members abut on adjacent side surfaces of the apparatus.

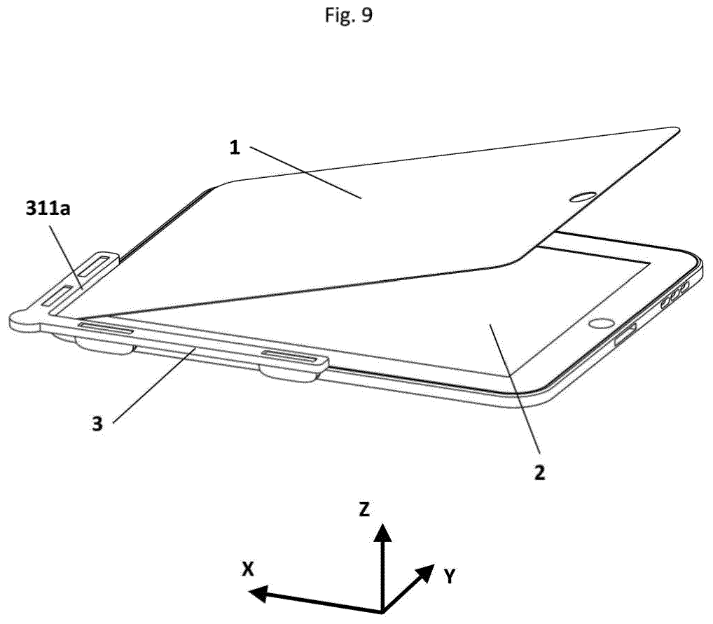

FIG. 9 shows how the display protector 1 is first placed against the first alignment portion 311a and then tilted about the transverse direction Y to be joined to the display 2 of the apparatus.

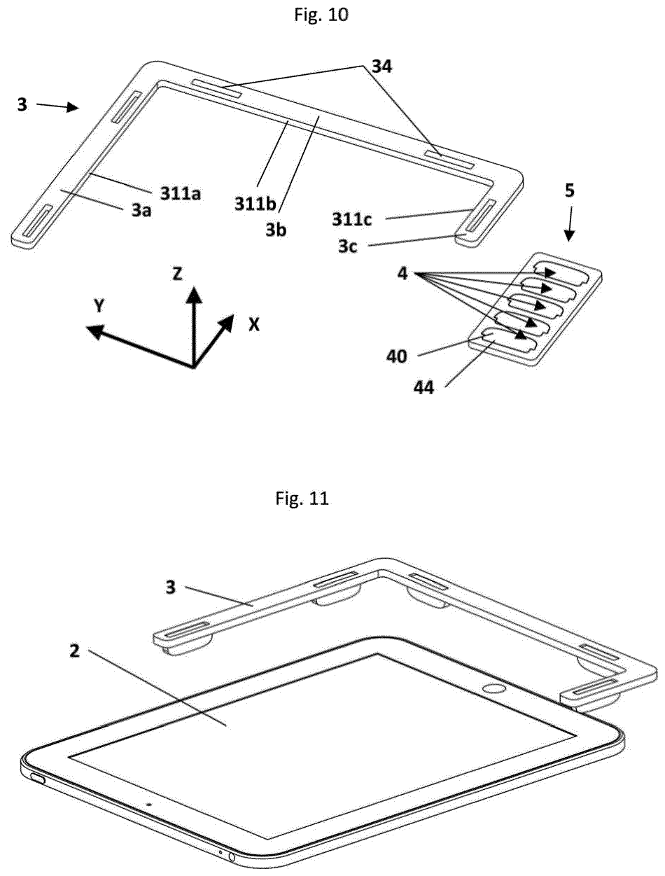

FIG. 10 shows a third embodiment of a mounting device according to the invention. In the third embodiment, the contact element 3 consists of three legs 3a, 3b, 3c. The first leg 3a is perpendicular to the second leg 3b. The third leg 3c is perpendicular to the second leg 3b and parallel to the first leg 3a. The first leg 3a and the third leg 3c point in the same direction.

The length of the second leg 3b corresponds to the width of an apparatus. The first leg 3a has a significantly greater length than the third leg 3c. Viewed from the display normal direction Z, this results in a J-shape for the contact element 3. The first leg 3a and the second leg 3b serve to position the mounting device on the apparatus. The third leg 3c prevents the mounting device from being displaced in the transverse direction Y parallel to the second leg 3b.

The first and second legs 3a, 3b each have two frame coupling portions 34. The third leg 3c has one frame coupling portion 34. A total of five positioning members 4 can thus be coupled to the contact element 3.

In an initial state, the five positioning members 4 are provided in a smoothing-out member 5 by means of webs 33.

FIG. 11 shows positioning members 4 detached from the smoothing-out member 5 and coupled to the contact element 3. The mounting device is placed on the apparatus from the display normal direction Z.

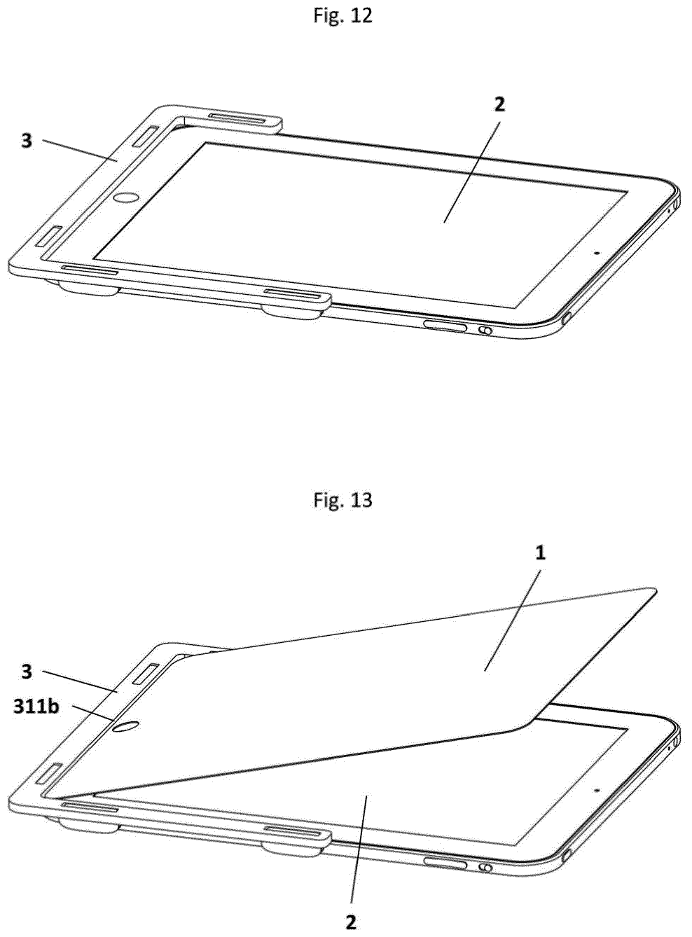

FIG. 12 shows the contact element 3 positioned on the apparatus with display 2. In the present embodiment, the display 2 of the apparatus is such that the mounting device can be positioned on the apparatus on both sides in the longitudinal direction X in order to join the display protector 1 to the display 2.

FIG. 13 shows the display protector 1 abutting on the second alignment portion 311b and on the display 2. By tilting the display protector 1 around the transverse direction Y, the display protector 1 can be joined to the display 2.

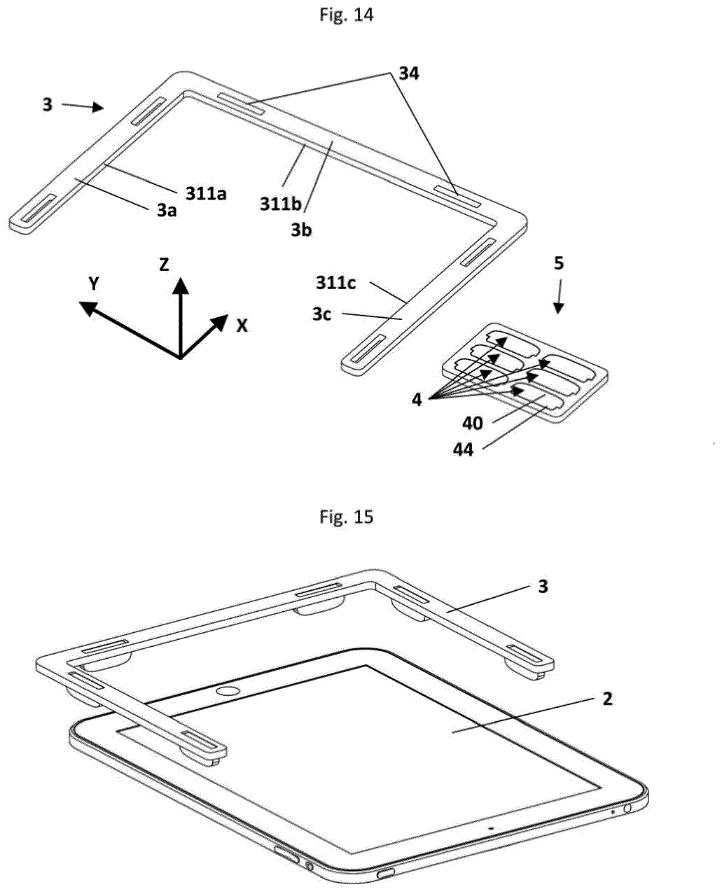

FIG. 14 shows a fourth embodiment of a mounting device according to the invention. In the fourth embodiment, the contact element 3 consists of three legs 3a, 3b, 3c. The first leg 3a is perpendicular to the second leg 3b. The third leg 3c is perpendicular to the second leg 3b and parallel to the first leg 3a. The first leg 3a and the third leg 3c point in the same direction.

The length of the second leg 3b corresponds to a width of an apparatus. The first leg 3a and the third leg 3c have the same length. This results in a U-shape for the contact element 3. The first leg 3a and the second leg 3b serve to position the mounting device on the apparatus. The third leg 3c prevents the mounting device from being displaced in the transverse direction Y parallel to the second leg 3b.

All legs 3a, 3b, 3c each have two frame coupling portions 34. A total of six positioning members 4 can thus be coupled to the contact element 3.

In an initial state, the six positioning members 4 are provided in a smoothing-out member 5 by means of webs 33.

FIG. 15 shows the positioning members 4 detached from the smoothing-out member 5 and coupled to the contact element 3. The mounting device is placed on the apparatus from the display normal direction Z.

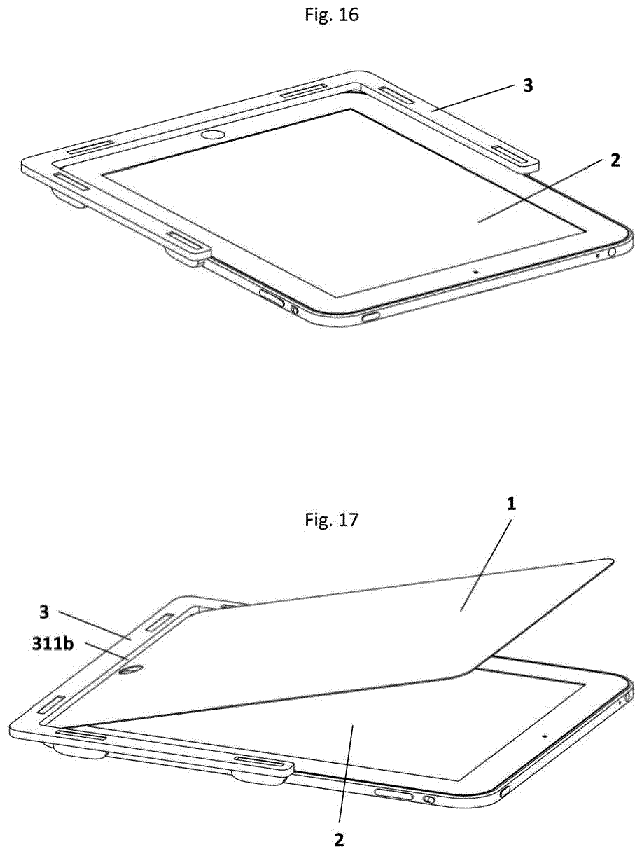

FIG. 16 shows the contact element 3 positioned on the apparatus with display 2.

FIG. 17 shows the display protector 1 abutting on the second alignment portion 311b and on the display 2. By tilting the display protector 1 around the transverse direction Y, the display protector 1 can be joined to the display 2.

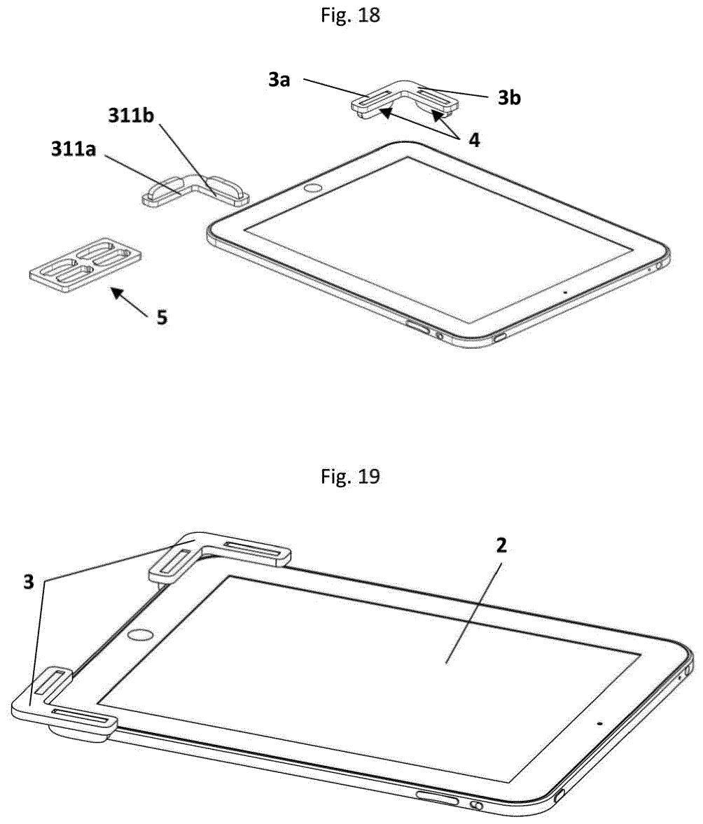

FIG. 18 shows a fifth embodiment of a mounting device according to the invention. In the fifth embodiment, two identical L-shaped contact elements 3 are used, each having two legs 3a, 3b, which are provided perpendicular to each other. The legs 3a and 3b have the same length and each have a frame coupling portion 34. Thus, a total of two positioning members 4 are coupled to one contact element 3.

In an initial state, the contact elements 4 can be provided in a smoothing-out member 5 by means of webs 33. In an initial state, the contact element 3 can be provided by means of webs on the alignment portions 311a, 311b of the two contact elements 3. The two contact elements 3, the smoothing-out member 5 and the four positioning members 4 thus form a common plate form.

FIG. 19 shows positioning members 4 detached from the smoothing-out member 5 and coupled to the two contact elements 3. The mounting devices are placed on the apparatus from the display normal direction at adjacent corners of the apparatus. The positioning portions 40 thereby contact the side surfaces of the apparatus. The two contact elements 3 are thus positioned on the apparatus with display 2.

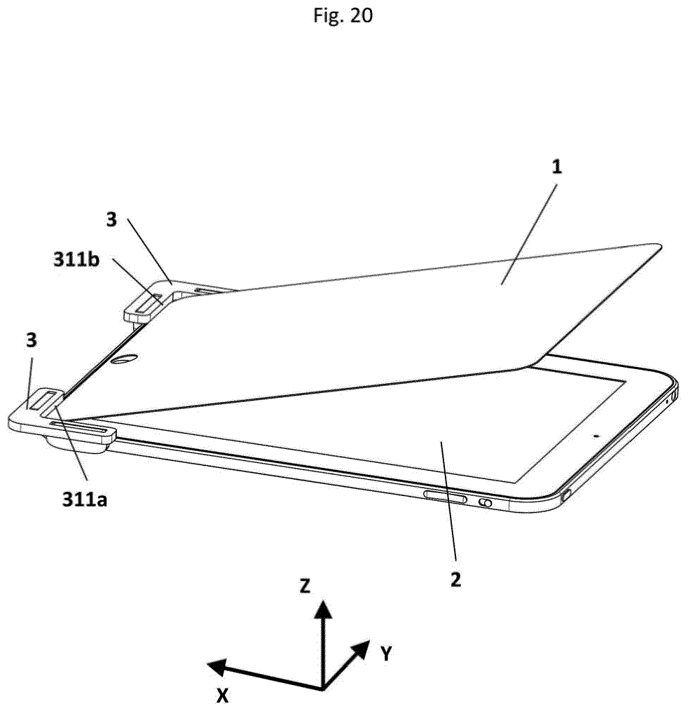

FIG. 20 shows a display protector 1 abutting on the first alignment portion 311a of the one contact element 3, the second alignment portion 311b of the other contact element 3 and the display 2. By tilting the display protector 1 around the transverse direction Y, the display protector 1 can be joined to the display 2.

1. (canceled)

2. A mounting device for joining a display protector to a display of an apparatus, the mounting device including:
a contact element on which the apparatus is positionable and which has a first leg with a first alignment portion on which the apparatus can be aligned in a first direction, and a second leg with a second alignment portion on which the apparatus can be aligned in a second direction,
a leg connecting portion that connects the two legs at a fixed angle, and
a first positioning member and a second positioning member comprising a plurality of positioning members having coupling portions which can be coupled to the legs, and positioning portions which are aligned with respect to the first alignment portion and with respect to the second alignment portion when the first positioning member is coupled to the first leg and the second positioning member is coupled to the second leg, wherein the display protector can be brought into contact with at least one positioning portion for alignment in order to align the apparatus and the display protector with respect to each other.

3. The mounting device according to claim 1, wherein the positioning members project beyond the alignment portions of the contact element, when viewed against a display normal direction (Z), when the positioning members are coupled to the legs and the apparatus is positioned with the mounting device.

4. The mounting device according to claim 3, wherein the contact element or the positioning members have a support portion where the display and/or the apparatus contacts the mounting device.

5. The mounting device according to claim 4, wherein the alignment portions are flat surfaces.

6. The mounting device according to claim 5, wherein the alignment portions are arranged at an angle to a joining surface (XY), wherein the joining surface (XY) corresponds to the connecting surface of the display and the display protector.

7. The mounting device according to claim 6, wherein the alignment portions are aligned with each other at an angle in the joining surface (XY).

8. The mounting device according to claim 7, wherein the alignment portions are connected by an alignment connecting portion.

9. The mounting device according to claim 8, wherein the first and second legs are arranged such that an L-shape is obtained for the contact element.

10. The mounting device according to claim 9, wherein the contact element has a third leg with a third alignment portion, where a leg connecting portion connects with the first and/or second leg at a fixed angle.

11. The mounting device according to claim 10, wherein the legs are arranged such that a U-shape is obtained for the contact element.

12. The mounting device according to claim 10, wherein the legs have different lengths and are arranged such that a J-shape is obtained for the contact element.

13. The mounting device according to claim 12, wherein the mounting device includes at least one further positioning member with a positioning portion, which is arranged on the first leg, the second leg or the third leg.

14. The mounting device according to claim 13, wherein positioning members can be coupled to one another by of positioning member coupling portions.

15. The mounting device according to claim 14, wherein a positioning portion is provided with an adhesive element which comes into contact with the apparatus or the display protector such that the positioning member adheres to the apparatus or the display protector.

16. The mounting device according to claim 15, wherein an alignment portion is provided with an adhesive element which comes into contact with the apparatus or the display protector such that the contact element adheres to the apparatus or the display protector.

17. The mounting device according to claim 16, wherein an adhesive element is covered with an adhesive element cover.

18. The mounting device according to claim 17, wherein the contact element comprises a grip portion.

19. The mounting device according to claim 18, wherein the leg connecting portion is designed to be integral with legs or as a separate connectable part.

20. The mounting device according to claim 19, wherein a height of a positioning member in the plate thickness direction is adjusted such that the positioning member does not touch the ground when the apparatus is positioned with the positioning member.

21. The mounting device according to claim 19, wherein a thickness of the contact element is adjusted such that the contact element does not touch the ground when the apparatus is positioned with the contact element.

22. The mounting device according to claim 20, wherein a positioning member is configured to be displaceable in a coupling portion perpendicularly to the joining surface (XY) and is provided with an adhesive element on a side facing a ground, with which the positioning member is positionable on the ground such that the positioning member adheres to the ground and the display and/or the apparatus contact the support portion.

23. The mounting device according to claim 21, wherein an adhesive element is arranged on a side of the contact element facing the ground, with which the contact element is positionable on the ground such that the contact element adheres to the ground with the adhesive element and the display and/or the apparatus contact the support portion.

24. The mounting device according to claim 23, wherein the mounting device additionally comprises an adhesive support by means of which the mounting device and/or the apparatus can adhere to the ground.

25. The mounting device according to claim 24, wherein the contact element has a plate form and the one side is a plate upper side and the other side is a plate bottom side.

26. The mounting device according to claim 25, wherein a frame coupling portion consists of an elongated cut-out which is continuous in the plate thickness direction and can be coupled to the coupling portion of the positioning member.

27. The mounting device according to claim 26, wherein an area on the plate bottom side of the contact element serves as a stop which restricts the movement of a positioning member in the plate thickness direction.

28. The mounting device according to claim 27, wherein the contact element additionally has a plate-shaped coupling lock that is connected to the contact element in the frame coupling portion by means of at least one web.

29. The mounting device according to claim 28, wherein a positioning member, which is plate-shaped, is connected to the contact element by means of at least one web.

30. The mounting device according to claim 29, wherein a central plate is connected to the contact element by means of at least one web.

31. The mounting device according to claim 30, wherein a positioning member is connected to the central plate by means of at least one web.

32. The mounting device according to claim 31, wherein a smoothing-out member is connected to the central plate by means of at least one web within the central plate.

33. The mounting device according to claim 32, wherein at least one positioning member is connected to the smoothing-out member by means of a web within the smoothing-out member .

34. The mounting device according to claim 33, wherein the smoothing-out member is positioned in the central plate so as to cover an area of the apparatus projecting against the display normal direction (Z) on a bottom side of the apparatus when the apparatus is positioned with the contact element.

35. The mounting device according to claim 34, wherein an apparatus holding element is connected to the central plate by means of at least one web within the central plate.

36. The mounting device according to claim 35, wherein a positioning portion has operating element cut-outs which expose projecting areas of the apparatus or the display in a direction parallel to the joining surface (XY).

37. The mounting device according to claim 36, wherein the contact element has a labeling area.
